(19) United States
(12) Patent Application Publication
(10) Pub. No.: US 2012/0248166 A1
(43) Pub. Date: Oct. 4, 2012

(54) Mounting apparatus

(76) Inventors: Adam Gold, Scarsdale, NY (US); Wayne Chen, Los Angeles, CA (US)

(21) Appl. No.: 13/065,912

(22) Filed: Apr. 1, 2011

(51) Int. Cl. B60R 11/00; F16F 7/00; F16M 13/00; H05K 7/14

(52) U.S. Cl. 224/545; 248/309.1; 248/636; 248/288.31

(57) ABSTRACT

A mounting assembly for interconnecting a first object and a second object has a link assembly having a first end that couples the first object, and a second end that couples the second object, and a top plate assembly coupled to the second end of the link assembly. The top plate assembly includes an upper plate having a plurality of holes for attachment to a receiving device or electronic device, and a lower plate coupled to the second end of the link assembly. The lower plate is connected to the upper plate only through a plurality of shock and vibration absorption members, thereby improving the shock and vibration absorption effect.

### BACKGROUND OF THE INVENTION

1. Field of the Invention

The present invention relates to a flexible mounting apparatus, and in particular, to an improved universal mounting apparatus that can be used to mount electronic devices to motorcycles, the mounting apparatus including shock and vibration absorption members.

2. Description of the Prior Art

Motorcycle riders are increasingly mounting electronic devices to their motorcycles. These devices can include GPS units, cell phones, music players, radios, radar detectors, and other items. These electronic devices are often not designed to withstand the substantial shock and vibrations produced by a motorcycle. Therefore, it is advantageous to have a mount that will reduce the shock and vibrations experienced by the electronic device.

Many electronic devices are also beginning to standardize the mounting hole locations. A common standardization is the AMPS hole pattern. The AMPS hole pattern consists of 4 holes in a rectangular pattern spaced 1.50″×1.19″ apart. Some devices do not have this pattern, but can be mounted on a flat plate using double sided tape or hook and loop fastener. To accommodate both of these mounting methods, it is advantageous to have a mount that has a flat top plate with an AMPS hole pattern.

There are many different types of mounts available on the market for mounting such electronic devices to a motorcycle or other vehicle. Most of these mounts provide an AMPS hole pattern, but have no means for absorbing vibration. Therefore, it would be advantageous to have a vibration absorbing module that can be connected to many different types of mounts having an AMPS hole pattern.

### SUMMARY OF THE INVENTION

In order to accomplish the above-described and other objects of the present invention, the present invention provides a mounting assembly for interconnecting a first object and a second object. The mounting assembly has a link assembly having a first end that couples the first object, and a second end that couples the second object, and a top plate assembly coupled to the second end of the link assembly. The top plate assembly includes an upper plate having a plurality of holes for attachment to a receiving device or an electronic device, and a lower plate coupled to the second end of the link assembly. The lower plate is connected to the upper plate only through a plurality of shock and vibration absorption members, thereby improving the shock and vibration absorption effect.

### BRIEF DESCRIPTION OF THE DRAWINGS

FIG. 1 is an exploded perspective view of a mounting apparatus according to one embodiment of the present invention shown in use holding a radar detector on a handlebar of a motorcycle.

FIG. 2 is an exploded perspective view of the mounting apparatus of FIG. 1.

FIG. 3 is a perspective view of the mounting apparatus of FIG. 1 shown in an assembled state.

FIG. 4 is an exploded perspective view of a top plate assembly for the mounting apparatus of FIG. 1.

FIG. 5 is another exploded perspective view of the upper plate and the dampers of the top plate assembly of FIG. 4.

FIG. 6 is a perspective view of the portion of the top plate assembly of FIG. 5 shown in an assembled state.

FIG. 7 is a cross-sectional view of a damper according to the present invention.

### DETAILED DESCRIPTION OF THE PREFERRED EMBODIMENTS

The following detailed description is of the best presently contemplated modes of carrying out the invention. This description is not to be taken in a limiting sense, but is made merely for the purpose of illustrating general principles of embodiments of the invention. The scope of the invention is best defined by the appended claims.

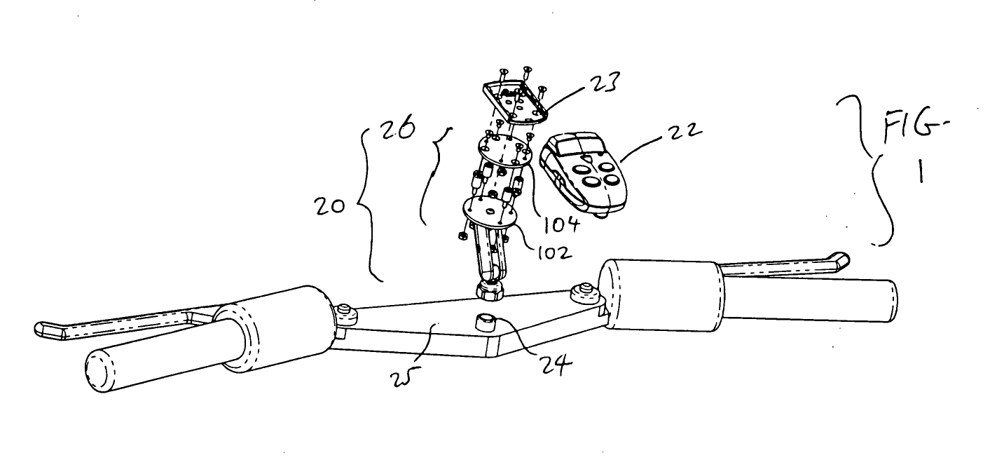

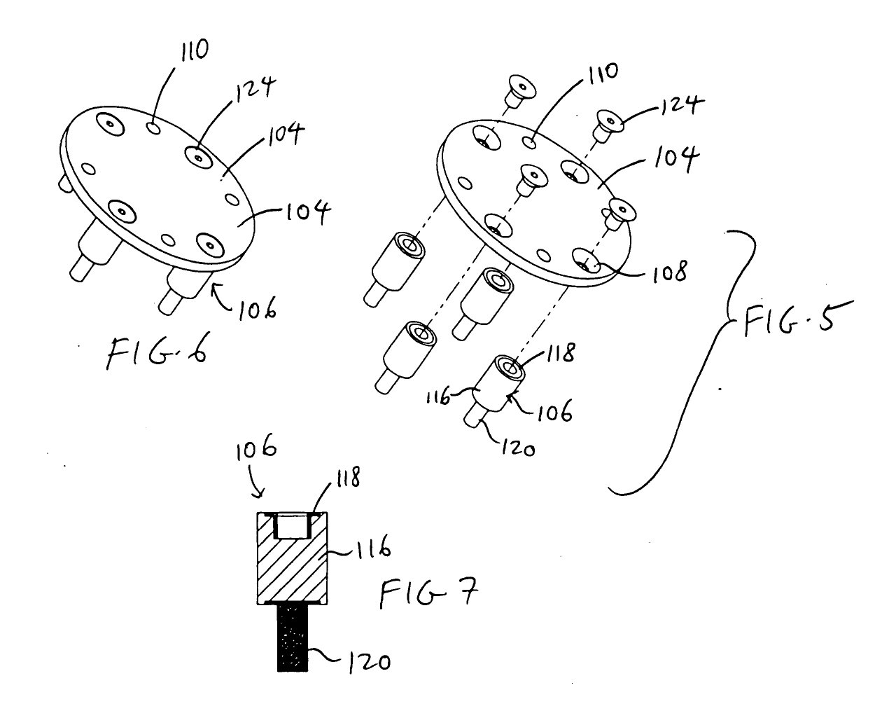

FIGS. 1-7 illustrate a mounting apparatus 20 according to the present invention. In FIG. 1, the mounting apparatus 20 is shown supporting a conventional radar detector 22 on the yoke stem 24 of a handlebar 25 of a conventional motorcycle. As such, the handlebar 25 functions as a supporting base. In this embodiment, the yoke stem 24 (and the handlebar 25) is the stationary object and the radar detector 22 is the movable object. The radar detector 22 is removably secured to a receiving device (e.g., cradle 23) that is connected to a top plate assembly 26 via screws 132 (see FIG. 4). The top plate assembly 26 is pivotably (e.g., including rotatably) connected to the top end of the mounting apparatus 20.

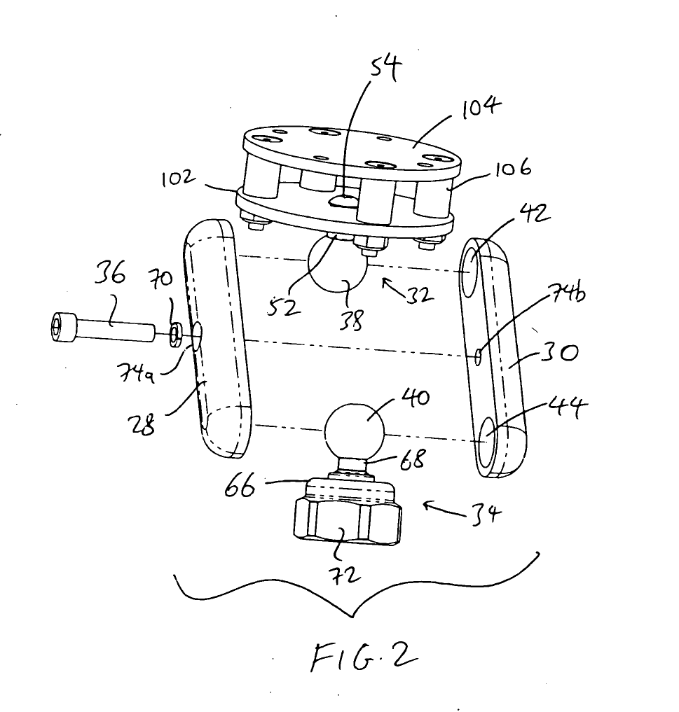

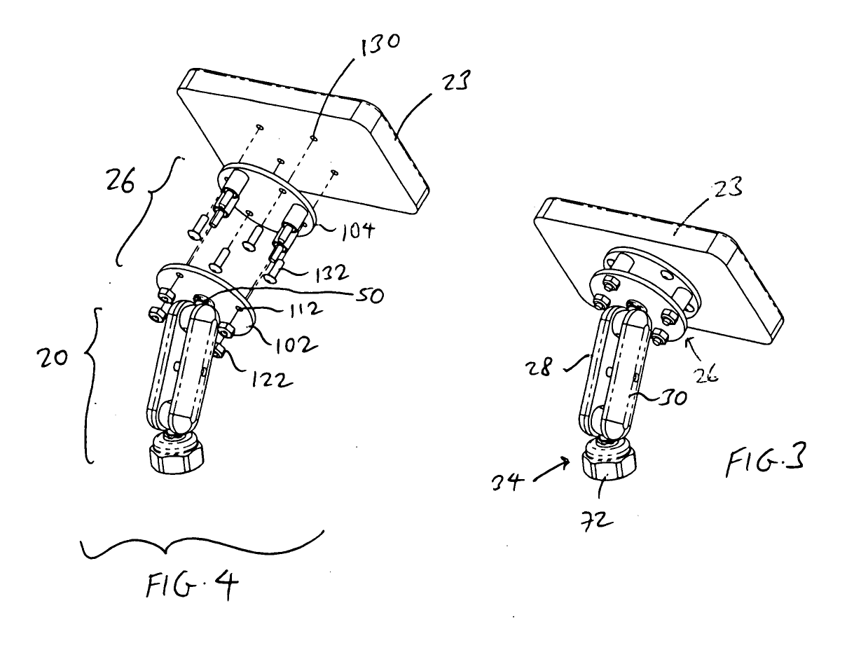

Referring to FIGS. 2-4, the mounting apparatus 20 comprises a split-arm assembly that has two separate and rigid link sections 28 and 30, an upper coupler 32, a lower coupler 34, and a link screw 36. The link sections 28 and 30 are essentially identical except that their holes 74a, 74b are slightly different. The link section 28 has a countersink and clearance hole 74a, while the other link section 30 has a tapped hole 74b. The upper coupler 32 has a spherical upper ball 38 and the lower coupler 34 has a spherical lower ball 40. Each link section 28, 30 has an upper socket section 42 and a lower socket section 44 positioned adjacent the upper and lower ends, respectively. The link sections 28, 30 are clamped together with the upper ball 38 retained inside the space defined by the upper socket sections 42, and with the lower ball 40 retained inside the space defined by the lower socket sections 44. The link screw 36 functions to clamp the link sections 28, 30 together with the help of a washer 70, by extending through holes 74a and 74b provided at about the center of each link section 28 and 30, respectively.

The upper coupler 32 has a disc-shaped base 50 (see FIG. 4) with a reduced-diameter neck 52 connecting the upper ball 38 and the base 50. The top plate assembly 26 is connected to the base 50 by a screw 54. The top plate assembly 26 will be described in greater detail below.

The lower coupler 34 has a disc-shaped base 66 with a reduced-diameter neck 68 connecting the upper ball 40 and the base 66. A yoke nut 72 is secured to the base 66, with the yoke nut 72 adapted to be threadably connected to the yoke stem 24 using known techniques.

The balls 38, 40, the link sections 28, 30 and the bases 50 and 66 are preferably made of the same material, and the material can be a metal, or a plastic. These elements can be made of the same or different materials, but they should all have the same material hardness so that one component does not deform or damage the other.

Referring now to FIGS. 4-7, the top plate assembly 26 includes an upper plate 104 and a lower plate 102. Both plates 102 and 104 are generally circular in configuration and can be provided in the form of flat discs, and both can be sized and configured to be the same as each other so that they can both be arranged parallel to each other, and separated by a plurality (e.g., four) of dampers 106. The upper plate 104 has a plurality (e.g., four) of damper mounting holes 108 that are spaced apart around the periphery of the upper plate 104, and a plurality (e.g., four) of connecting holes 110 that are offset from the damper mounting holes 108, and also spaced apart around the periphery of the upper plate 104. Both sets of holes 108 and 110 can be arranged in an AMPS pattern. The lower plate 102 has a plurality (e.g., four) of holes 112 that are spaced apart around the periphery of the lower plate 102, and can be aligned with the damper mounting holes 108 of the upper plate 104. The lower plate 102 is rigidly connected to the base 50 of the upper coupler 32 by the screw 54 whose head is seated between the upper plate 104 and the lower plate 102 (see FIG. 2).

Each damper 106 has a cylindrical body 116 with an open top end that allows a threaded metal insert 118 to be positioned therein. A threaded metal post 120 extends from the bottom end of the body 116. Each damper 106 is connected between the plates 102 and 104 by first inserting the post 120 through a corresponding hole 112 in the lower plate 102, threading a nut 122 to the post 120 to secure the post 120 to the lower plate 102, then aligning the top end of the damper 106 and its insert 118 to a corresponding damper mounting hole 108 at the upper plate 104, and threading a screw 124 through the damper mounting hole 108 and into the insert 118. Therefore, as best shown in FIGS. 3-4, the upper plate 104 only connects to the lower plate 102 through the dampers 106, thereby producing a vibration and shock absorbing effect. Therefore, the dampers 106 function as vibration and shock absorbing members. In this regard, the body 116 is preferably made of a material that promotes damping or absorption of vibrations, such as a thermoplastic or thermoset rubber such as PVC, Neoprene, or Urethane, with a hardness durometer of 20-60 Shore A.

The connecting holes 110 in the upper plate 104 define an AMPS hole pattern to allow a device cradle (e.g., for a radar detector) to be mounted thereto. Referring to FIGS. 1, 3 and 4, in the present embodiment, for example, the cradle 23 can have four holes 130 arranged in an AMPS hole pattern so that the cradle 23 can be mounted to the upper plate 104 using four screws 132 that extend through the four connecting holes 110 in the upper plate 104, and the holes 130 in the cradle 23. The screws 132 extend only through the upper plate 104 (and not through the lower plate 102) and the cradle 23, thereby reducing vibration. The screws 132 can be inserted to facilitate the connection of the cradle 23 before the dampers 106 are secured to the lower plate 102, as shown in FIG. 4. Alternatively, the screws 132 can be inserted from the upper surface of the cradle 23 after the dampers 106 are secured to the lower plate 102, as shown in FIG. 1. As best shown in FIG. 1, the cradle 23 can have two opposing side bars that are connected by a rear bar, with the front edge of the cradle 23 is opened, so that the side bars can act as rails for allowing the radar detector 22 to be slid on to the cradle 23 via corresponding rails on the bottom or side of the radar detector 22.

The top plate assembly 26 provides numerous benefits. It has a flat upper plate 104, which allows it to have a low profile. It facilitates universal use by providing the standard AMPS hole patterns. The low profile and standard hole patterns allow for a wide variety of different devices 22 and cradles 23 to be attached to the upper plate 104. The top plate assembly 26 provides excellent shock and vibration absorption because only the dampers 106 connect the upper plate 104 and the lower plate 102. Finally, the flat upper plate 104 allows for the use of double-sided adhesive tape or Velcro™, which can be useful for devices such as radar detectors that do not have cradles.

As an additional benefit, since the dampers 106 (and their corresponding threaded posts 120 and inserts 118) are positioned in an AMPS pattern, the upper plate 104 and the dampers 106 can be packaged separately from the lower plate 102, and then the packaged upper plate 104 and dampers 106 can be used on any other mount with a plate that also has an AMPS hole pattern.

Even though the mounting apparatus 20 is shown and described in connection with the yoke nut 72 and top plate assembly 26 for use in an automotive (or motorcycle) environment to support a radar detector 22, these are merely non-limiting examples. The mounting apparatus 20 and top plate assembly 26 of the present invention can be applied to other applications and used with other connecting mechanisms. Examples include LCD monitors and GPS units, among others.

While the description above refers to particular embodiments of the present invention, it will be understood that many modifications may be made without departing from the spirit thereof. The accompanying claims are intended to cover such modifications as would fall within the true scope and spirit of the present invention.

What is claimed is:

1. A mounting assembly for interconnecting a first object and a second object, the mounting assembling including a link assembly having a first end that couples the first object, and a second end that couples the second object, and a lower plate pivotably coupled to the second end of the link assembly, the improvement comprising:
an upper plate having a plurality of holes for attachment to an electronic device or a receiving device, and wherein the upper plate is connected to the lower plate only through a plurality of shock and vibration absorption members.

2. The assembly of claim 1, wherein the shock and vibration absorption members are dampers.

3. The assembly of claim 2, wherein each damper has a cylindrical body with an open top end that allows a threaded metal insert to be positioned therein, the damper further having a metal post extending from a bottom end of the body.

4. The assembly of claim 3, wherein the upper plate has a plurality of damper mounting holes, and the lower plate has a plurality of holes that are aligned with the damper mounting holes of the upper plate, with the post of each damper extending through and secured at one of the holes in the lower plate by a nut, and wherein a screw extends through each aligned damper mounting hole from the upper plate and a corresponding insert in the damper to connect the upper plate to the lower plate.

5. The assembly of claim 1, further including a receiving device or an electronic device that is attached via screws to some of the holes in the upper plate.

6. The assembly of claim 1, wherein the upper plate is a flat plate.

7. The assembly of claim 1, wherein the link assembly comprises:
first and second rigid link sections, each link section having an upper socket section and a lower socket section, so that an upper receiving space is defined by the two upper socket sections and a lower receiving space is defined by the two lower socket sections;
an upper coupler having an upper ball that is received for rotation inside the upper receiving space, with the lower plate secured to the upper coupler;
a lower coupler having a lower ball that is received for rotation inside the lower receiving space, with the stationary object secured to the lower coupler; and
a link member for securing the link sections together with the upper ball retained inside the upper receiving space, and with the lower ball retained inside the lower receiving space.

8. The assembly of claim 1, further including a receiving device or an electronic device that is attached via double-sided tape or VELCRO™ pads to the upper plate.

9. The assembly of claim 1, wherein the first object is a stationary object and the second object is a movable object.

10. An assembly, comprising:
an electronic device;
a receiving device for receiving the electronic device;
a vehicle; and
a mounting assembly for interconnecting a portion of the vehicle and the receiving device, the mounting assembly having a link assembly having a first end that couples the vehicle, and a second end, the mounting assembly further including a lower plate pivotably coupled to the second end of the link assembly, the improvement comprising:
an upper plate having a plurality of holes for coupling to the receiving device, and wherein the upper plate is connected to the lower plate only through a plurality of shock and vibration absorption members.

11. The assembly of claim 10, wherein the shock and vibration absorption members are dampers.

12. The assembly of claim 11, wherein each damper has a cylindrical body with an open top end that allows a threaded metal insert to be positioned therein, the damper further having a metal post extending from a bottom end of the body.

13. The assembly of claim 12, wherein the upper plate has a plurality of damper mounting holes, and the lower plate has a plurality of holes that are aligned with the damper mounting holes of the upper plate, with the post of each damper extending through and secured at one of the holes in the lower plate by a nut, and wherein a screw extends through each aligned damper mounting hole from the upper plate and a corresponding insert in the damper to connect the upper plate to the lower plate.

14. The assembly of claim 10, wherein the receiving device is attached via screws to some of the holes in the upper plate.

15. The assembly of claim 10, wherein the upper plate is a flat plate.

16. The assembly of claim 10, wherein the link assembly comprises:
first and second rigid link sections, each link section having an upper socket section and a lower socket section, so that an upper receiving space is defined by the two upper socket sections and a lower receiving space is defined by the two lower socket sections;
an upper coupler having an upper ball that is received for rotation inside the upper receiving space, with the lower plate secured to the upper coupler;
a lower coupler having a lower ball that is received for rotation inside the lower receiving space, with the stationary object secured to the lower coupler; and
a link member for securing the link sections together with the upper ball retained inside the upper receiving space, and with the lower ball retained inside the lower receiving space.
